(19) United States
(12) Patent Application Publication
(10) Pub. No.: US 2005/0134880 A1
(43) Pub. Date: Jun. 23, 2005

(54) Color error diffusion method and apparatus therefor

(76) Inventors: Ki-min Kang, Seongnam-si (KR); Goo-soo Gahang, Yongin-si (KR); Choon-woo Kim, Seoul (KR); Hyeon-seok Seo, Incheon Metropolitan-city (KR)

Correspondence Address: ROYLANCE, ABRAMS, BERDO & GOODMAN, L.L.P., 1300 19TH STREET, N.W., SUITE 600, WASHINGTON,, DC, 20036, US

(21) Appl. No.: 10/996,059

(22) Filed: Nov. 24, 2004

(30) Foreign Application Priority Data
Nov. 26, 2003 (KR) 2003-84708

(51) Int. Cl. G06F 15/00; G03F 3/08

(52) U.S. Cl. 358/1.9; 358/3.03; 358/518

(57) ABSTRACT

An apparatus and method of diffusing a color error which includes modulating a threshold value using a binary error of different color channels, to prevent overlapping of dots of a channel, when a sum of input values of the different color channels is not more than a predetermined value, determining a channel whose color is to be output by comparing a corrected input value of each channel in which an error is diffused and binarizing a color channel by comparing the modulation threshold value with the corrected input value of the determined channel.

### CROSS REFERENCE TO RELATED APPLICATIONS

This application claims the benefit under 35 U.S.C. 119(a) of Korean Patent Application No. 2003-84708, filed on Nov. 26, 2003, in the Korean Intellectual Property Office, the entire contents of which is incorporated herein by reference.

### BACKGROUND OF THE INVENTION

1. Field of the Invention

The present invention relates to halftoning. More particularly, the present invention relates to a method of diffusing a color error to generate a high quality color image and simultaneously improve a calculation speed and reduce use of a memory space, and an apparatus therefor.

2. Description of the Related Art

In binary output devices such as digital printers, copiers, and binary output Liquid Crystal Displays (LCDs), a variety of color senses are substantially represented with only two colors, that is, black and white. For example, for a black and white digital printer, a black and white image displayed on a monitor is represented with only two values of black and white. To output a black and white image having a variety of brightness which is displayed on the monitor through a black and white printer, a series of processes are required to convert an input image to a binary image on a printer or PC. That is, a process of converting the color of each pixel to an image in a gray scale having brightness values of 0 (white)-255 (black) and a process of converting the image in a gray scale to a binary image occurs. An image having brightness values between 0 (white) and 255 (black) is referred to as a continuous gradation image. A process of converting the gradation image to a binary image is referred to as halftoning. There are various halftoning methods available. Error diffusion, one of such methods, is widely used as a typical method.

FIG. 1 is a flow chart illustrating a conventional color halftoning method for reducing the overlapping of dots between color channels. In FIG. 1, IN1 and IN2 are sums of color input signals and C+M and C+m+Y are used therefor. Since each of the color input signals is compared with a threshold value, not as it is but by being converted to a single signal, a result similar to a binary result of a single channel halftoning can be obtained. A method of performing binarization by converting an input value to a single signal is advantageous in that an output not overlapping uniform distribution of pixels can be obtained compared to a method of performing binarization for each channel. However, since uniform distribution of each channel is not taken into consideration, an artifact is generated because pixels of a particular color are arranged in one direction.

An ideal color binary image must have no unpleasant pattern and accurately represent a desired color. Most unpleasant patterns in a binary image obtained by single channel halftoning are generated because dots of the binary image are not uniformly distributed. However, in the binary image obtained by a color halftoning, print quality is dominated by not only the patterns generated by irregular distribution of dots but also BY a big difference in brightness or color with surrounding pixels.

In particular, a degree of irregularity to the eye is higher in a blue dot which is formed as a cyan dot overlapping a magenta dot in a bright area, than the other color dots. Thus, the output of such a blue pixel in a highlight area should be prevented.

### SUMMARY OF THE INVENTION

To solve the above problems and to provide other benefits, embodiments of the present invention provide a method of diffusing a color error which enables a uniform distribution of pixels between channels, without having output pixels of cyan and magenta channels overlapping each other, using a threshold value modulation method, and an apparatus therefor.

According to an aspect of the present invention, a method of diffusing a color error comprises modulating a threshold value using a binary error of different color channels, to prevent overlapping of dots of a channel, when a sum of input values of the different color channels is less than a predetermined value, determining a channel whose color is to be output by comparing a corrected input value of a each channel in which an error is diffused, and binarizing a color channel by comparing the modulation threshold value with the corrected input value of the determined channel.

The channel is a cyan channel and a magenta channel and the predetermined value is 255. The modulation of the threshold value uses a sum of errors of the cyan channel diffused from surrounding pixels for the magenta channel and uses a sum of errors of the magenta channel diffused from surrounding pixels for the cyan channel.

The threshold value of the magenta channel is calculated by the following equation

$$Tm ( m , n ) = 128 - α \times {\sum }_{( k , l ) ∈ R}^{} w ( k , l ) Ce ( m - k , n - l ) ,$$

and the threshold value of the cyan channel is calculated by the following equation

$$Tc ( m , n ) = 128 - α \times {\sum }_{( k , l ) ∈ R}^{} w ( k , l ) Me ( m - k , n - l ) ,$$

wherein “m” and “n” denote coordinates of a pixel, “Tc” denotes a threshold value of cyan, “Ce” and “Me” denote error values of the cyan and magenta channels, respectively, “w” is an error diffusion coefficient, and α denotes a constant to adjust a range of fluctuations of the threshold value.

According to another aspect of the present invention, the constant α is calculated by the following equation:

$$α = \{ \begin{matrix}0.6 & 0 < C + M \leq 16 \\ 0.3 & 16 < C + M \leq 56 \\ 0.1 & 56 < C + M\end{matrix} .$$

### BRIEF DESCRIPTION OF THE DRAWINGS

The above and other features and advantages of the present invention will become more apparent by describing in detail preferred embodiments thereof with reference to the attached drawings in which:

FIG. 1 is a flow chart for explaining a conventional color halftoning method for reducing overlapping of dots between color channels;

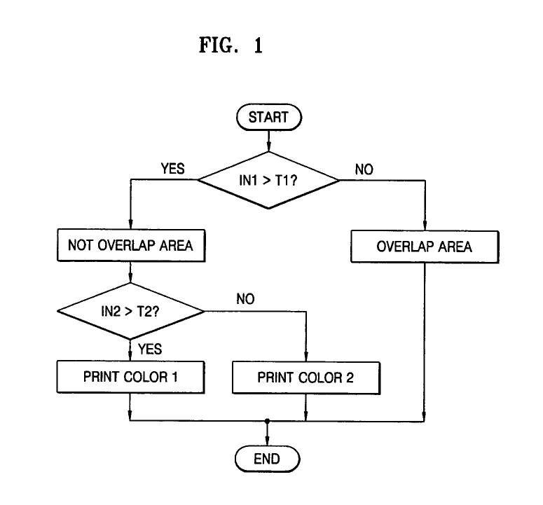

FIG. 2 is a flow chart illustrating a process for color error diffusion according to an embodiment of the present invention;

FIG. 3 is a table listing sums of errors transmitted by surrounding pixels; and

FIG. 4 is a block diagram showing the configuration of a binary error diffusion apparatus which uses a binary error diffusion method according to an embodiment of the present invention.

Throughout the drawings, it should be noted that the same or similar elements are denoted by like reference numerals.

### DETAILED DESCRIPTION OF EXEMPLARY EMBODIMENTS

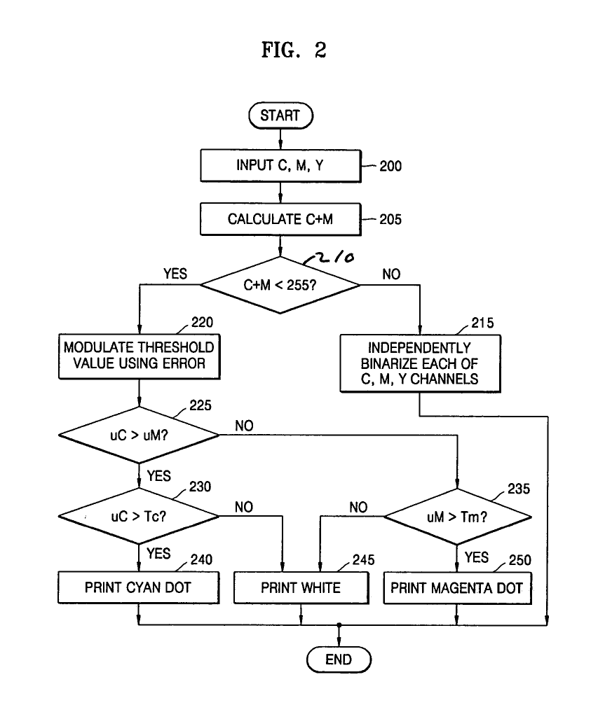

Referring to FIG. 2, when cyan, magenta, and yellow channel values are input (Step 200), a sum (C+M) of the input values of the cyan and magenta channels is obtained (Step 205).

If it is required that dot overlapping between two channels not be generated, output pixels of the two channels are binarized not to overlap each other by using a threshold value modulation method. To this end, a gradation value which prevents generation of dot overlapping between two channels is set such that the sum of input values of the cyan and magenta channels is not greater than 255. Thus, whether the sum of the input valves of the cyan and magenta channels is less than 255 is checked (Step 210). If the sum of the input valves of the cyan and magenta channels is not less than 255, each of the cyan, magenta, and yellow channels is independently binarized like the single channel binarization (Step 215).

In the single channel binarization, since a binary image is represented by two of a white point (0) and a black point (255), the distribution of points of the binary image is dominated by a value of one of the black point and the white point which exists in larger numbers. That is, when an input image is greater than 128 (an absolute value corresponding to an intermediary value of a continuous gradation input image), since the black points exist in larger numbers than the white point, the white point is referred to as a minor pixel and the distribution of the white point which is the minor pixel determines the quality of the binary image. When the input gradation value is less than 128, since the black point becomes a minor pixel, the quality of an image is affected by the distribution of the black point. The error diffusion method is used as a typical method of generating a binary image is expressed as in Equation 1 through 3.

$$u ( m , n ) = x ( m , n ) + {\sum }_{( k , l ) ∈ R}^{} w ( m - k , n - l ) e ( m , n ) \qquad [ Equation 1 ]$$

e(m,n)=u(m,n)−b(m,n) [Equation 2]

$$\begin{matrix}b ( m , n ) = 255 & if u ( m , n ) \geq T \\ = 0 & else\end{matrix} \qquad [ Equation 3 ]$$

In Equations 1 through 3, “x(m, n)” denotes a continuous gradation input value of a pixel, “w(k, l)” denotes an error diffusion coefficient limited to an R area with respect to a pixel (m, n), and “e(m, n)” denotes a binarization error value after a binary pixel value is determined in the pixel (m, n). “T” denotes a threshold value. The threshold value T is typically set to 128.

If the sum of the input values of the cyan and magenta channels is less than 255 in Step 210, a modulated threshold value is obtained using a threshold value modulation method to prevent generation of dot overlap between two channels (Step 220). The threshold value modulation method is performed according to Equations 4 and 5.

$$\begin{matrix}Tm ( m , n ) = 128 - α \times {\sum }_{( k , l ) ∈ R}^{} w ( k , l ) Ce ( n - k , n - l ) & [ Equation 4 ] \\ Tc ( m , n ) = 128 - α \times {\sum }_{( k , l ) ∈ R}^{} w ( k , l ) Me ( m - k , n - l ) & [ Equation 5 ]\end{matrix}$$

In Equations 4 and 5, “m” and “n” denote coordinates of a pixel, “k” and “l” denote positional displacements of neighboring pixels for calculating an error sum with respect to “m” and “n”, “Tc” and “Tm” denote threshold values of cyan and magenta, respectively, “Ce” and “Me” denote error values of the cyan and magenta channels, respectively, “w” is an error diffusion coefficient, and α denotes a constant for adjusting a range of fluctuations of the threshold value.

After modulating a threshold value according to Equations 4 and 5, corrected input values (uC, uM) which are error-diffused with respect to the cyan and magenta channels are obtained and compared with each other (Step 225). Then, each color channel is binarized. The corrected input values (Ce, Me) for the respective color channels may be obtained, for example, by using a Floyd-Steinberg's error diffusion processing method.

Specifically, when the corrected cyan channel value uC is greater than the corrected magenta channel value uM, whether the corrected cyan channel value uC is greater than the modulated threshold value Tc of the cyan channel is determined (Step 230). When the cyan channel value uC is greater than the modulated threshold value Tc of the cyan channel, the cyan dot is printed (Step 240). Otherwise, white is printed (Step 245).

When the corrected cyan channel value uC is not greater than the corrected magenta channel value uM in Step 225, whether the corrected magenta channel vale uM is greater than the modulated threshold value Tm with respect to the magenta channel obtained in Step 220 is compared (Step 235). When the magenta channel value uM is greater than the modulated threshold value Tm of the cyan channel, the magenta dot is printed (Step 250). Otherwise, white is printed (Step 245).

Equation 6 shows a change of the constant α in Equations 4 and 5 according to the input value C+M. Since a predetermined ideal distance is large in a highlight area, the amount of a change of the threshold value should be large. As the main distance decreases, the amount of a change of the threshold value becomes smaller.

$$α = \{ \begin{matrix}0.6 & 0 < C + M \leq 16 \\ 0.3 & 16 < C + M \leq 56 \\ 0.1 & 56 < C + M\end{matrix} \qquad [ Equation 6 ]$$

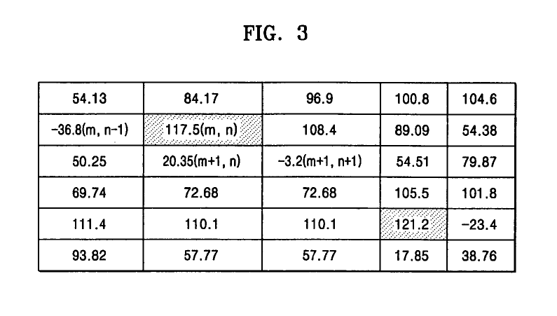

FIG. 3 shows sums of errors propagated by surrounding pixels. Provided that a Serpentine scan is used, binarization is performed from the left to the right in the first row and from the right to the left in the second row. In FIG. 3, when a pixel (m, n) is binarized to 255, a smaller value of an error occurs than when the pixel is binarized to 0. Since a small error value is propagated at a pixel located at positions (m, n−1), (m+1, n), and (m+1, n+1), the sum of the affected errors is small. Thus, when the error spreads uniformly, the distribution of a minority of pixels can be recognized by using an error distribution characteristic without using the minimum pixel distance information.

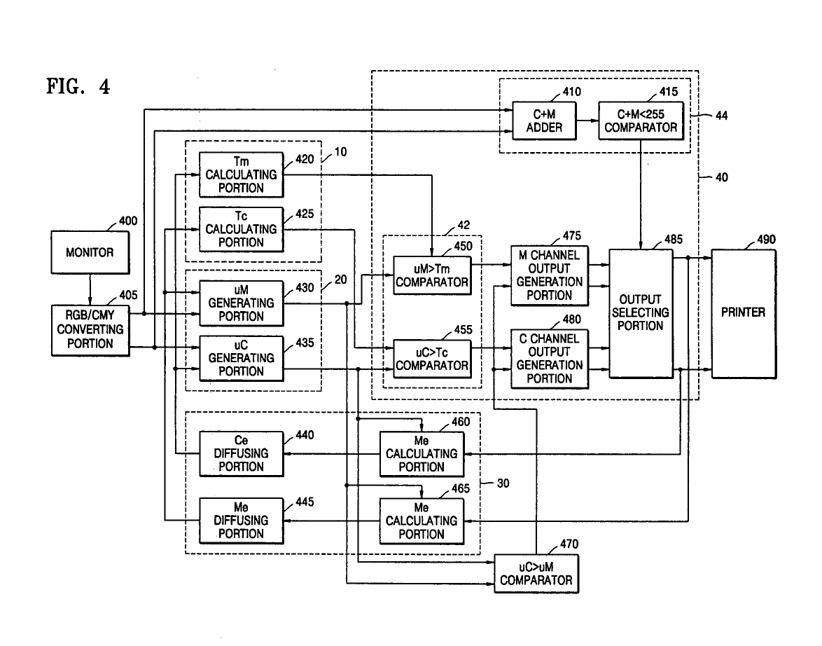

FIG. 4 is a block diagram illustrating a binary error diffusion apparatus which uses a binary error diffusion method according to an embodiment of the present invention. The binary error diffusion apparatus includes an RGB/CMY converting portion 405, an error diffusing portion 30, a threshold value modulating portion 10, a channel value updating portion 20, a uC>uM comparator 470, and a channel output portion 40.

The RGB/CMY converting portion 405 converts an RGB signal output from a monitor 400 to a CMY signal. The error diffusing portion 30 calculates a binarization error of a channel obtained by a difference between updated cyan and magenta channel values and a binary output value and diffuses the binarization error using a predetermined error diffusion coefficient, and includes a Ce diffusing portion 440, a Me diffusing portion 445, a Ce calculating portion 460, and a Me calculating portion 465.

A uM generating portion 430 calculates a uM value by using a magenta error diffused value M_{D} calculated using the Me diffusing portion 445. A uC generating portion 435 calculates a uC value by using a cyan error diffused value C_{D} calculated by the Ce diffusing portion 440. The uM and uC may be determined by, for example, Equation 1.

The Ce diffusing portion 440 calculates C_{D} according to Equation 7 by considering an error diffusion coefficient w by using a cyan error Ce calculated by the Ce calculating portion 460.

$${C}_{D} = {\sum }_{( k , l ) ∈ R}^{} w ( k , l ) Ce ( m - k , n - l ) \qquad [ Equation 7 ]$$

The Me diffusing portion 445 calculates M_{D} according to Equation 8 by considering an error diffusion coefficient w by using a magenta error Me calculated by the Me calculating portion 465.

$${M}_{D} = {\sum }_{( k , l ) ∈ R}^{} w ( k , l ) Me ( m - k , n - l ) \qquad [ Equation 8 ]$$

The uM>Tm comparator 450 compare the uM value generated by the uM generating portion 430 and the Tm value calculated by the Tm calculating portion 420. The uC>Tc comparator 455 compares the uC value generated by the uC generating portion 435 and the Tc value calculated by the Tc calculating portion 425.

The Ce calculating portion 460 calculates a Ce value by using the uC value generated by the uC generating portion 435 and a binarized value selected by an output selecting portion 485. For example, the Ce value can be obtained by Equation 2. The Me calculating portion 465 calculates a Me value by using the uM value generated by the uM generating portion 430 and a binarized value selected by the output selecting portion 485. For example, the Me value can be obtained by Equation 2.

The threshold value modulating portion 10 modulates a threshold value of a magenta channel by using a binarization error of a cyan channel where a binarization error is diffused by the error diffusing portion 30 and a threshold value of a cyan channel by using a binarization error of a magenta channel, and includes a Tm calculating portion 420 and a Te calculating portion 425. The Tm calculating portion 420 calculates a Tm value using Equation 4 by multiplying the constant α determined by Equation 6 to the cyan error diffused value C_{D} calculated by the Ce diffusing portion 440. The Tc calculating portion 425 calculates a Tc value by Equation 5 by multiplying the constant α determined by Equation 6 with the magenta error diffused value M_{D} calculated by the Me diffusing portion 445.

The channel value updating portion 20 updates a channel value by adding the input cyan and magenta channel values and the error diffused channel value, and includes the uM generating portion 430 and the uC generating portion 435.

The uC>uM comparator 470 compares the updated channel values of the C and M channels output from the channel value updating portion 20. That is, the uC>uM comparator 470 compares the value generated from the uC generating portion 435 and the value generated from the uM generating portion 430.

The channel output portion 40 compares the modulated threshold value and the updated channel value and binarizes a color channel, and includes a threshold value comparing portion 42, a channel adding/comparing portion 44, an M channel output generating portion 475, a C channel output generating portion 480, and the output selecting portion 485.

The threshold value comparing portion 42 compares the updated channel value and a threshold value corresponding to the channel, and includes a uM>Tm comparator 450 and the uC>Tc comparator 455.

The channel adding/comparing portion 44 adds the cyan channel value and the magenta channel value and compares whether the sum is less than 255, and includes a C+M adder 410 and a C+M<255 comparator 415. The C+M adder 410 adds the C channel value and the M channel value output from the RGB/CMY converting portion 425. The C+M<255 comparator 415 compares whether the output value of the C+M adder 410 is less than 255 and controls the output of the output selecting portion 485 according to the result of the comparison.

The M channel output generating portion 475 binarizes the magenta channel when the updated cyan channel value uC is not greater than the updated magenta channel value uM and the updated magenta channel value uM is greater than the modulated magenta channel threshold value Tm, and generates white (W) when the updated magenta channel value uM is not greater than the modulated magenta channel threshold value Tm. That is, the M channel output generating portion 475 operates when the uC>uM comparator 470 compares the uC value with the uM value and the uC value is determined to be less than the uM value. When the uC value is less than the uM value, the output of the M channel output generating portion 475 varies according to the result of the comparison of the uM>Tm comparator 450. When the uM value is greater than the Tm value, the binarized magenta channel value M is output. When the uM value is not greater than the Tm value, the binarized W (white) value is output.

The C channel output generating portion 480 binarizes the cyan channel when the updated cyan channel value uC is not greater than the updated magenta channel value uM and the cyan channel value uC is greater than the modulated cyan channel threshold value Tc, and generates white (W) which is printed when the updated cyan channel value uC is not greater than the modulated cyan channel threshold value Tc. That is, the C channel output generating portion 480 operates when the uC>uM comparator 470 compares the uC value with the uM value and the uC value is determined to be less than the uM value. When the uC value is less than the uM value, the output of the C channel output generating portion 480 varies according to the result of the comparison of the uC>Tc comparator 455. When the uC value is greater than the Tc value, the binarized cyan channel value C is output. When the uC value is not greater than the Tc value, the binarized W (white) value is output.

The output selecting portion 485 outputs output values of the M channel output generating portion and the C channel output generating portion when the value obtained by adding the cyan channel value and the magenta channel value by the channel adding/comparing portion 44 is less than 255. That is, the C+M<255 comparator 415 compares the C+M value and 255 and, when the C+M value is less than 255, the output selecting portion 485 outputs an input value. The magenta channel value, the cyan channel value, and the white value respectively output from the first output generating portion 475 and the second output generating portion 480 are input to the output selecting portion 485. The value output from the output selecting portion 485 is printed by the printer 490.

The operation of the binary error diffusion apparatus according to an embodiment of the present invention is the same as that of the binary error diffusion method described with reference to FIG. 2.

The present invention may be embodied on a computer recordable recording medium as codes readable by the computer. The computer readable recording medium includes all types of recording apparatuses which can store data readable by a computer system. For example, there are Read Only Memories (ROMs), Random Access Memories (RAMs), Compact Discs (CD)-ROMs, magnetic tapes, floppy disks, and optical data storing apparatuses, and the like as the computer readable recording medium. Also, recording medium in a carrier wave format (for example, transmission through the Internet) can be included therein. The computer readable recording medium is distributed in a computer system connected through a network and computer readable codes are stored and executed in a distribution method.

While this invention has been particularly shown and described with reference to certain embodiments thereof, it should be understood by those skilled in the art that various changes in form and details may be made therein without departing from the spirit and scope of the invention as defined by the appended claims.

As described above, according to the present invention, since a threshold value modulation method is used for a channel while maintaining a uniform distribution of pixels for each color channel, the uniform distribution of pixels between the channels can be maintained.

1. A method of diffusing a color error comprising:
modulating a threshold value using a binary error of different color channels, to prevent overlapping of dots of a channel, when a sum of input values of the different color channels is not more than a predetermined value;
determining a channel whose color is to be output by comparing a corrected input value of each channel in which an error is diffused; and
binarizing a color channel by comparing the modulation threshold value with the corrected input value of the determined channel.

2. The method of claim 1, wherein the channel comprises a cyan channel and a magenta channel and the predetermined value comprises 255.

3. The method of claim 2, wherein the modulation of the threshold value uses a sum of errors of the cyan channel diffused from surrounding pixels for the magenta channel and uses a sum of errors of the magenta channel diffused from surrounding pixels for the cyan channel.

4. The method of claim 2, wherein the threshold value of the magenta channel is calculated by the following equation
$$Tm ( m , n ) = 128 - α \times {\sum }_{( k , l ) ∈ R}^{} w ( k , l ) Ce ( m - k , n - l ) ,$$
and the threshold value of the cyan channel is calculated by the following equation
$$Tc ( m , n ) = 128 - α \times {\sum }_{( k , l ) ∈ R}^{} w ( k , l ) Ce ( m - k , n - l ) ,$$
wherein “m” and “n” denote coordinates of a pixel, “Tc” denotes a threshold value of cyan, “Ce” and “Me” denote error values of the cyan and magenta channels, respectively, “w” is an error diffusion coefficient, and a denotes a constant to adjust a range of fluctuation of the threshold value.

5. The method of claim 4, wherein the constant α is calculated by the following equation
$$α = \{ \begin{matrix}0.6` & 0 < C + M \leq 16 \\ 0.3 & 16 < C + M \leq 56 \\ 0.1 & 56 < C + M\end{matrix}$$

6. An apparatus for diffusing a color error comprising:
an error diffusing portion which calculates a binary error of a channel obtained from a difference between updated cyan and magenta channel values and binary output value and diffuses the binary error by a predetermined error diffusion coefficient;
a threshold value modulating portion which modulates a threshold value of a magenta channel using a binary error of a cyan channel where a binary error is diffused by the error diffusing portion and modulates a threshold value of the cyan channel using a binary error of the magenta channel;
a channel value updating portion which updates a channel value by adding input cyan and magenta channel values and the error diffused channel value;
a uC>uM comparator which compares the updated channel values of the cyan (C) and magenta (M) channels output from the channel value updating portion; and
a channel output portion which binarizes a color channel by comparing the modulated threshold value with the updated channel value.

7. The apparatus of claim 6, wherein the channel output portion comprises:
a threshold value comparing portion which compares the updated channel value and a threshold value corresponding to the channel;
a channel adding/comparing portion-which adds the cyan channel value and the magenta channel value and compares whether the added value is less than 255;
a magenta (M) channel output generating portion which binarizes the magenta channel when an updated cyan channel value (uC) is not greater than an updated magenta channel value (uM) and an updated magenta channel value (uM) is greater than a modulated magenta channel threshold value (Tm), and prints white (W) when the updated magenta channel value (uM) is not greater than the modulated magenta channel threshold value (Tm);
a cyan (C) channel output generating portion which binarizes the cyan channel when the updated cyan channel value (uC) is greater than the updated magenta channel value (uM) and the updated cyan channel value (uC) is greater than a modulated cyan channel threshold value (Tc), and prints white (W) when the updated cyan channel value (uC) is not greater than the modulated cyan channel threshold value (Tc); and
an output selecting portion which outputs output values of the magenta channel output generating portion and the cyan channel output generating portion when a value obtained by adding the cyan channel value and the magenta channel values by the channel adding/comparing portion is less than 255.

8. The apparatus of claim 7, wherein the threshold value of the magenta channel is calculated by the following equation
$$Tm ( m , n ) = 128 - α \times {\sum }_{( k , l ) ∈ R}^{} w ( k , l ) Ce ( m - k , n - l ) ,$$
and the threshold value of the cyan channel is calculated by the following equation
$$Tc ( m , n ) = 128 - α \times {\sum }_{( k , l ) ∈ R}^{} w ( k , l ) Me ( m - k , n - l ) ,$$
wherein “m” and “n” denote coordinates of a pixel, “Tc” denotes a threshold value of cyan, “Ce” and “Me” denote error values of the cyan and magenta channels, respectively, “w” is an error diffusion coefficient, and α denotes a constant to adjust a range of fluctuation of the threshold value.

9. The apparatus of claim 8, wherein the constant α is calculated by the following equation
$$α = \{ \begin{matrix}0.6` & 0 < C + M \leq 16 \\ 0.3 & 16 < C + M \leq 56 \\ 0.1 & 56 < C + M\end{matrix}$$

10. A computer readable recoding medium for storing a program to control a system to diffuse a color error comprising:
a first set of instructions for controlling the system to modulate a threshold value using a binary error of different color channels, to prevent overlapping of dots of a channel, when a sum of input values of the different color channels is not more than a predetermined value;
a second set of instructions for controlling the system to determine a channel whose color is to be output by comparing a corrected input value of each channel in which an error is diffused; and
a third set of instructions for controlling the system to binarize a color channel by comparing the modulation threshold value with the corrected input value of the determined channel.
